(19) United States
(12) Patent Application Publication
(10) Pub. No.: US 2026/0205109 A1
(43) Pub. Date: Jul. 16, 2026

(54) DIRECT DRIVE CASCODED SWITCHING CIRCUIT

(71) Applicant: SEMICONDUCTOR COMPONENTS INDUSTRIES, LLC, Scottsdale, AZ (US)

(72) Inventors: Karel PTACEK, Roznov pod Radhostem (CZ); Roman RADVAN, Roznov pod Radhostem (CZ)

(73) Assignee: SEMICONDUCTOR COMPONENTS INDUSTRIES, LLC, Scottsdale, AZ (US)

(21) Appl. No.: 19/355,755

(22) Filed: Oct. 10, 2025

Related U.S. Application Data
(63) Continuation-in-part of application No. 19/016,239, filed on Jan. 10, 2025.

(51) Int. Cl. H03K 17/16; H02M 1/088; H02M 3/158

(52) U.S. Cl. CPC H03K 17/162; H02M 1/088; H02M 3/158

(57) ABSTRACT

A cascoded switch system includes a JFET, a MOSFET, and a cascode-drive circuit comprising (i) a drain-sense circuit to compare a drain voltage against a drain threshold, (ii) a logic gate to assert a cascode-on signal based on an input signal on-state or the drain voltage being less than the drain threshold, and to assert a cascode-off signal based on an input signal off-state and the drain voltage being greater than the drain threshold, (iii) a JFET drive circuit to drive the JFET on in response to the cascode-on signal, and with a negative voltage in response to the cascode-off signal, (iv) a comparator to compare the JFET gate voltage against a threshold, and (v) a MOSFET drive circuit to force the MOSFET on in response to the cascode-on signal, and force the MOSFET on or off based on the comparator output and in response to the cascode-off signal.

The present application is a continuation-in-part of U.S. patent application Ser. No. 19/016,239 filed January 10, 2025, entitled “Direct Drive Cascoded Switching Circuit,” to inventors Karel Ptacek and Roman Radvan.

### TECHNICAL FIELD

The disclosure relates generally to integrated circuit technology, and particularly to switching circuits.

### BACKGROUND

Power electronics may be used to control the conversion and distribution of electric power. For example, switching power converters may be used to create a direct current (“DC”) voltage from an alternating current (“AC”) voltage by switching current through a magnetic element such as an inductor. Conversely, inverters can be used to convert a DC voltage to an AC voltage. In these and other forms of power electronics, power switches may be used to control the conversion and flow of power through the power-conversion system and to the electronic circuitry to be powered by the device.

Cascoded switches may be used as the power switch in power conversion systems to drive high currents and to withstand large voltages. Inventors of embodiments of the present disclosure have recognized that cascoded switches may suffer from unstable oscillations and drain-voltage overshoots due to inductive loads and the turn-off characteristics of the cascoded switch. Inventors of embodiments of the present disclosure have also recognized that such drain-voltage overshoots may damage the components of the cascoded switch unless otherwise constricted with an additional and costly R-C snubber across the drain to source of the cascoded switch. Embodiments of the present disclosure may address one or more of these challenges.

### SUMMARY

The examples herein enable a cascoded switch system implemented to reduce or elimination oscillations and/or drain-voltage overshoots while also improving system-level efficiency.

According to one example, a cascoded switch system includes a cascoded switch comprising a JFET and a MOSFET coupled in series between a drain terminal and a source terminal of the cascoded switch, and a cascode-drive circuit comprising (i) a drain sense circuit configured to compare a drain voltage at the drain terminal against a drain threshold, (ii) a logic gate configured to assert a cascode-on signal in response to either of an on-state of an input signal or the drain voltage being less than the drain threshold, and to assert a cascode-off signal in response to an off-state of the input signal and the drain voltage being greater than the drain threshold, (iii) a JFET drive circuit configured to drive the JFET in a JFET on-state in response to the cascode-on signal, and to drive the JFET with a negative voltage in response to the cascode-off signal, (iv) a comparator configured to compare a JFET gate voltage against a JFET-gate threshold, and (v) a MOSFET driver circuit configured to drive the MOSFET in a MOSFET on-state in response to the cascode-on signal, and to drive the MOSFET in one of a MOSFET off-state and the MOSFET on-state based on a comparison signal from the comparator and in response to the cascode-off signal. In some embodiments, the drain threshold is negative relative to a source voltage of the source terminal. In the same or different embodiments, the MOSFET driver circuit is configured to drive the MOSFET in the MOSFET on-state in response to an assertion of the cascode-off signal and the comparator indicating that the JFET gate voltage is sufficient to drive the JFET in a JFET off-state. In the same or different embodiments, the MOSFET driver circuit is configured to drive the MOSFET in the MOSFET off-state in response to an assertion of the cascode-off signal and the comparator indicating that the JFET gate voltage is not sufficient to drive the JFET in a JFET off-state. In the same or different embodiments, the JFET is a silicon carbide JFET and the MOSFET is a silicon MOSFET. In the same or different embodiments, the JFET, the MOSFET, and the cascode-drive circuit are co-packaged in a multi-die integrated circuit package. In the same or different embodiments, the JFET drive circuit comprises (i) a JFET driver coupled to output a JFET-drive signal to a capacitor coupled in series between the JFET driver and a gate of the JFET in response to an output of the logic gate, (ii) a switch coupled between the gate of the JFET and the source terminal, the switch configured to be responsive to the output of the logic gate. In the same or different embodiments, a capacitance of the capacitor is greater than a gate capacitance of the JFET by a factor of at least 10. In the same or different embodiments, a capacitance of the capacitor is at least 10 nF. In the same or different embodiments, the cascoded switch system further includes a resistor coupled in series between the capacitor and the gate of the JFET. In the same or different embodiments, the switch coupled between the gate of the JFET and the source terminal comprises a PMOS transistor.

According to another example, a cascoded switch system includes a cascoded switch comprising a JFET and a MOSFET coupled in series between a drain terminal and a source terminal of the cascoded switch, and a cascode-drive circuit comprising (i) a drain sense circuit configured to compare a drain voltage at the drain terminal against a drain threshold, (ii) a logic gate configured to assert a cascode-on signal in response to either of an on-state of an input signal or the drain voltage being less than the drain threshold, and to assert a cascode-off signal in response to an off-state of the input signal and the drain voltage being greater than the drain threshold, (iii) a JFET drive circuit configured to drive the JFET in a JFET on-state in response to the cascode-on signal, and to drive the JFET with a negative voltage in response to the cascode-off signal, (iv) a comparator configured to compare a JFET gate voltage against a JFET-gate threshold, and (v) a MOSFET driver circuit configured to drive the MOSFET in a MOSFET on-state in response to the cascode-on signal, to drive the MOSFET in the MOSFET on-state in response to an assertion of the cascode-off signal and the comparator indicating that the JFET gate voltage is sufficient to drive the JFET in a JFET off-state, and to drive the MOSFET in an MOSFET off-state in response to the assertion of cascode-off signal and the comparator indicating that the JFET gate voltage is not sufficient to drive the JFET in the JFET off-state. In some embodiments, the drain threshold is negative relative to a source voltage of the source terminal. In the same or different embodiments, the JFET is a silicon carbide JFET and the MOSFET is a silicon MOSFET. In the same or different embodiments, the JFET, the MOSFET, and the cascode-drive circuit are co-packaged in a multi-die integrated circuit package. In the same or different embodiments, the JFET drive circuit comprises (i) a JFET driver coupled to output a JFET-drive signal to a capacitor coupled in series between the JFET driver and a gate of the JFET in response to an output of the logic gate, (ii) a switch coupled between the gate of the JFET and the source terminal, the switch configured to be responsive to the output of the logic gate. In the same or different embodiments, a capacitance of the capacitor is greater than a gate capacitance of the JFET by a factor of at least 10. In the same or different embodiments, a capacitance of the capacitor is at least 10 nF. In the same or different embodiments, the cascoded switch system further includes a resistor coupled in series between the capacitor and the gate of the JFET. In the same or different embodiments, the switch coupled between the gate of the JFET and the source terminal comprises a PMOS transistor.

Another example provides a method for operating a cascoded switch system, wherein the method includes comparing a drain voltage at a drain of a cascoded switch against a drain threshold, receiving a input signal, asserting a cascode-on signal in response to either of an on-state of the input signal or the drain voltage being less than the drain threshold, driving a JFET of the cascoded switch in a JFET on-state in response to the cascode-on signal, driving a MOSFET of the cascoded switch in a MOSFET on-state in response to the cascode-on signal, asserting a cascode-off signal in response to an off-state of the input signal and the drain voltage being greater than the drain threshold, driving the JFET of the cascoded switch with a negative drive voltage in response to the cascode-off signal, comparing a JFET gate voltage to a threshold to generate a comparison signal, and driving the MOSFET in response to the cascode-off signal and the comparison signal. In some embodiments, driving the MOSFET in response to the cascode-off signal and the comparison signal comprises driving the MOSFET in the MOSFET on-state in response to an assertion of the cascode-off signal and the comparison signal indicating that the JFET gate voltage is sufficient to drive the JFET in a JFET off-state. In some embodiments, driving the MOSFET in response to the cascode-off signal and the comparison signal comprises driving the MOSFET in a MOSFET off-state in response to an assertion of the cascode-off signal and the comparison signal indicating that the JFET gate voltage is not sufficient to drive the JFET in a JFET off-state. In the same or different embodiments, the drain threshold is negative relative to a source voltage of a source terminal of the cascoded switch. In the same or different embodiments, the method further includes charging a capacitor coupled in series with a gate of the JFET when driving the JFET in the JFET on-state. In the same or different embodiments, the method further includes applying a voltage stored across the capacitor as the negative drive voltage in response to the cascode-off signal. In the same or different embodiments, the JFET is a silicon carbide JFET, and the MOSFET is a silicon MOSFET.

### BRIEF DESCRIPTION OF THE DRAWINGS

A more complete understanding of the present embodiments may be acquired by referring to the following description taken in conjunction with the accompanying drawings, in which like reference numbers indicate like features.

FIG. 1 illustrates a schematic diagram of a power conversion system in accordance with embodiments of the present disclosure.

FIG. 2 illustrates a schematic diagram of a cascoded switch system in accordance with embodiments of the present disclosure.

FIG. 3 illustrates a schematic diagram of an example comparator in accordance with embodiments of the present disclosure.

FIG. 4 illustrates a plot diagram of example waveforms within a cascoded switch system in accordance with embodiments of the present disclosure.

FIG. 5 illustrates a plot diagram of example waveforms within a cascoded switch system in accordance with embodiments of the present disclosure.

FIG. 6 illustrates an example method of operating a cascoded switch system in accordance with embodiments of the present disclosure.

### DETAILED DESCRIPTION

Details of one or more embodiments are set forth in the description below and the accompanying drawings. Other features will be apparent from the description, drawings, and from the claims. The embodiments disclosed should not be interpreted, or otherwise used, as limiting the scope of the disclosure, including the claims. In addition, one skilled in the art understands that the following description has broad application, and the discussion of any embodiment is meant to be exemplary of that embodiment, and not intended to intimate that the scope of the disclosure, including the claims, is limited to that embodiment.

Various terms are used to refer to particular system components. Different companies may refer to a component by different names, and this disclosure does not intend to distinguish between components that differ in name but not form and function. In the following discussion and in the claims, the terms “including” and “comprising” are used in an open-ended fashion, and thus should be interpreted to mean “including, but not limited to.” Also, the term “couple” or “coupled” is intended to mean either an indirect or direct connection. Thus, if a first device couples to, or is coupled to, a second device, that connection between the first device and the second device may be through a direct connection or through an indirect connection via other devices and connections. As used herein, the term “and/or” includes any and all combinations of one or more of the associated listed items.

Further, although the terms “first,” “second,” and so forth may be used herein to describe various elements, these elements should not be limited by these terms. Terms such as “first” and “second” may be used merely to distinguish one element from another. For example, a first element could be termed a second element, and, similarly, a second element could be termed a first element, without departing from the scope of the present disclosure. Further, the identification of a “first” element, does not necessarily require the presence of a “second” element.

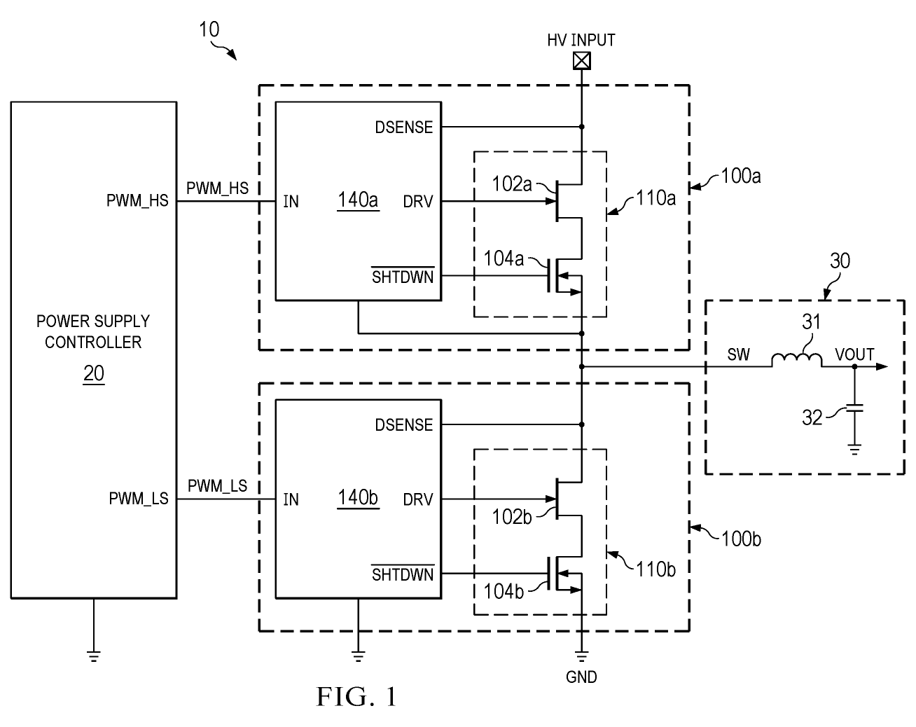

FIG. 1 illustrates a schematic diagram of power conversion system 10 in accordance with embodiments of the present disclosure. Power conversion system 10 may be implemented in suitable fashion according to the operation described in the present disclosure. In some embodiments, power conversion system 10 may include power supply controller 20, first cascoded switch system 100a, second cascoded switch system 100b, and load 30. First cascoded switch system 100a may include first cascode-drive circuit 140a and first cascoded switch 110a, which may in turn include first junction field-effect transistor (JFET) 102a and first metal-oxide semiconductor field-effect transistor (MOSFET) 104a. Second cascoded switch system 100b may include second cascode-drive circuit 140b and second cascoded switch 110b, which may in turn include second JFET 102b and a second MOSFET 104b.

As shown in FIG. 1, first cascoded switch system 100a and second cascoded switch system 100b may form a half-bridge circuit. For example, first cascoded switch system 100a may form the high side of the half-bridge circuit driven by a high-side pulse-width modulation signal PWM_HS. In turn, second cascoded switch system 100b may form the low side of the half-bridge circuit driven by a low-side pulse-width modulation signal PWM_LS. The PWM_HS and PWM_LS may be asserted in alternating fashion to drive first cascoded switch system 100a and second cascoded switch system 100b on and off in an alternating fashion from each other. For example, PWM_HS may be asserted at a logic-high level to turn on first cascoded switch system 100a while PWM_LS is asserted at a logic-low level to turn off second cascoded switch system 100b. Conversely, PWM_HS may be asserted at a logic-low level to turn off first cascoded switch system 100a while PWM_LS is asserted at a logic-high level to turn on second cascoded switch system 100b. To prevent shoot-through current from the high voltage input (HV INPUT) to ground (GND), both first cascoded switch system 100a and second cascoded switch system 100b may be driven in respective off-states for a non-overlap time before one of the first cascoded switch system 100a and second cascoded switch system 100b transitions to the on-state.

In some embodiments, first cascoded switch system 100a and second cascoded switch system 100b may be implemented as part of a buck switching power converter. For example, as shown in FIG. 1, load 30 may include an LC filter formed by inductor 31 and capacitor 32. Inductor 31 may have (i) a first terminal coupled to the switching node SW between first cascoded switch system 100a and second cascoded switch system 100b, and (ii) a second terminal coupled to capacitor 32. The LC filter may thus filter the voltage value at switching node SW to produce an output voltage VOUT that based on the duty cycle of PWM_HS and the corresponding time-averaged voltage at switching node SW.

Although FIG. 1 illustrates first cascoded switch system 100a and second cascoded switch system 100b implemented as part of a buck switching power converter, one or both of first cascoded switch system 100a and second cascoded switch system 100b may be implemented as part of any suitable switching system. For example, in some embodiments, load 30 may be implemented by a coil of a three-phase motor. In such embodiments, power supply controller 20, first cascoded switch system 100a, and second cascoded switch system 100b may represent one phase of a three-phase driver for the three-phase motor.

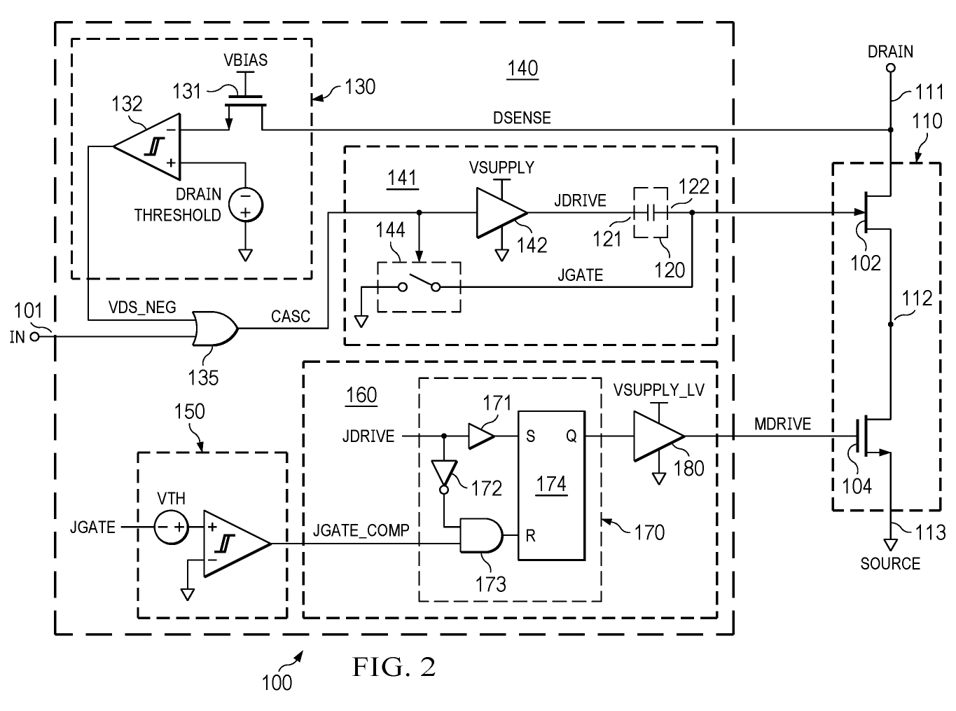

In applications such as a buck switching power converter application shown in FIG. 1, a reverse current may flow through the low-side cascoded switch (for example, second cascoded switch 110b) during the non-overlap time between the time that high-side cascoded switch turns off and the subsequent time that low-side cascoded switch turns on. In some applications, a reverse current may similarly flow through the high-side cascoded switch (for example, first cascoded switch 110a) during the non-overlap time between the time that the low-side cascoded switch turns off and the subsequent time that the high-side cascoded switch turns on. As described in detail below with reference to FIGS. 2-5, embodiments of the present disclosure may monitor for such a reverse current and provide further control to cascoded switch 110 to improve the efficiency of the cascoded switch system 100 during this non-overlap period. Although the description below with reference to FIGS. 2-5 refers to an example whereby the cascoded switch system 100 is implemented on the low-side of an H-bridge application (such as the buck power converter shown in FIG. 1), the same principles described below may apply equally to improve efficiency when cascoded switch system 100 is implemented on the high-side of an H-bridge application.

FIG. 2 illustrates a schematic diagram of cascoded switch system 100 in accordance with embodiments of the present disclosure. Cascoded switch system 100 may represent an embodiment of first cascoded switch system 100a and second cascoded switch system 100b described above with reference to FIG. 1. Cascoded switch system 100 may be implemented in suitable fashion according to the operation described in the present disclosure. As shown in FIG. 2, cascoded switch system 100 may include cascoded switch 110 and cascode-drive circuit 140. As described in further detail below, cascode-drive circuit 140 may be configured to drive cascoded switch 110 in response to an input signal IN.

Cascoded switch 110 may include JFET 102 and MOSFET 104 coupled in series between a drain terminal 111 and a source terminal 113 of cascoded switch 110. For example, JFET 102 may be coupled between a drain terminal 111 and a cascode node 112 of cascoded switch 110. JFET 102 may have a drain coupled to the drain terminal 111 of cascoded switch 110, and may have a source coupled to the cascode node 112. JFET 102 may be a depletion-mode device that may be normally on with a gate-to-source voltage of zero volts, and driven off with a gate-to-source voltage below a threshold of, for example, -4 volts, -6 volts, -8 volts, -12 volts, or less. For the purposes of illustration, embodiments of JFET 102 are described below with an gate-to-source threshold of, for example, -12 volts. MOSFET 104 may be coupled between the cascode node 112 and the source terminal 113 of cascoded switch 110. For example, MOSFET 104 may have a drain coupled to the source of JFET 102 at the cascode node 112, and may have a source coupled to the source terminal 113 of cascoded switch 110. MOSFET 104 may be an enhancement-mode device that may be normally off with a gate-to-source voltage of zero volts, and driven on with a gate-to-source voltage above a positive threshold.

Cascoded switch 110, and cascoded switch system 100 as a whole, may be utilized in either high-side and low-side switching applications. For example, in a half-bridge circuit application such as the buck switching power converter shown in FIG. 1, a first instance of cascode switch system 100 may form a high-side switch of the half-bridge circuit and a second instance of cascode switch system 100 may form a low-side switch of the half-bridge circuit. The internal circuitry of cascode-drive circuit 140 may be referenced from the source terminal 113, which may serve as the low-voltage supply rail for cascoded switch 110 and cascode-drive circuit 140. For example, as shown in FIG. 2, the internal circuitry of cascode-drive circuit 140 such as JFET driver 142, switch 144, and driver 180, may be referenced from the source terminal 113. In embodiments where cascoded switch system 100 serves as a low-side switch, source terminal 113 may be coupled to ground, and the internal circuitry of cascode-drive circuit 140 may thus be referenced to ground GND. And in embodiments where cascoded switch system 100 serves as a high-side switch, source terminal 113 may be coupled to a switching node SW, and the internal circuitry of cascode-drive circuit 140 may thus be referenced to the switching node SW. For either such low-side or high-side applications, a supply voltage VSUPPLY may also be supplied to the internal circuitry of cascode-drive circuit 140 at a voltage level sufficiently above the voltage of source terminal 113 to supply cascode-drive circuit 140 and to drive JFET 102 and MOSFET 104.

In some embodiments, MOSFET 104 may be an N-type MOSFET (NMOS or NMOS transistor). Further, MOSFET 104 may in some embodiments be a silicon MOSFET formed on a silicon substrate. MOSFET 104 may also be implemented in other semiconductor technologies, including silicon-carbide (SiC) or Gallium-Nitride (GaN). JFET 102 may in some embodiments be a silicon carbide JFET formed on a silicon carbide substrate. JFET 102 may also be formed in any other semiconductor technology suitable for producing a JFET with current-density and voltage stand-off properties suitable to serve as a cascode for a lower-voltage rated MOSFET. Further, in some embodiments, JFET 102 and MOSFET 104 may be co-packaged in a multi-die integrated circuit package. For example, JFET 102 may be implemented as a silicon carbide JFET, MOSFET 104 may be implemented as a silicon MOSFET, and the silicon-carbide-based die and the silicon-based die on which JFET 102 and MOSFET 104 are respectively implemented may be co-packaged together in a multi-die integrated circuit package. Further, in some embodiments, JFET 102, MOSFET 104, and cascode-drive circuit 140 may be co-packaged in a multi-die integrated circuit package. Although capacitor 120 is illustrated as part of cascode-drive circuit 140, capacitor 120 may be considered part of or separate from cascode-drive circuit 140, and may be implemented either on the same semiconductor die as the other elements of cascode-drive circuit 140 or separate from cascode-drive circuit 140. In some embodiments, capacitor 120 may be co-packaged with other components of cascode-drive circuit 140, JFET 102, and MOSFET 104 in a multi-die integrated circuit package. Further, in other embodiments, capacitor 120 may be implemented separate from a multi-die integrated circuit package including other components of cascode-drive circuit 140, JFET 102, and MOSFET 104.

Cascode-drive circuit 140 may be implemented in any suitable fashion according to the operation described in the present disclosure. As shown in FIG. 2, cascode-drive circuit 140 may include drain-sense circuit 130, logic gate 135, JFET drive circuit 141, comparator 150, and MOSFET drive circuit 160. Cascode-drive circuit 140 may be configured, in conjunction with capacitor 120, to drive JFET 102 and MOSFET 104 in response to an input signal IN received at input terminal 101 and/or in response to an indication from drain-sense circuit 130 that a reverse current is flowing through cascoded switch 110 from source terminal 113 to drain terminal 111.

Drain-sense circuit 130 may be configured to compare a drain voltage DSENSE at the drain terminal 111 against a drain threshold. For example, drain-sense circuit 130 may include transistor 131 and drain-sense comparator 132. Transistor 131 may be a high-voltage NMOS transistor with a drain coupled to the drain terminal 111 of cascoded switch 110, a gate driven by a bias voltage VBIAS, and a source coupled to an input of drain-sense comparator 132. In some embodiments, VBIAS may be set at a low-voltage value (for example, 5 V) sufficient for transistor 131 pass drain voltage values at or near the drain threshold, but to otherwise protect drain-sense comparator 132 from high voltages (for example, up to 400 volts or more) that may be present at drain terminal 111 at certain times of a switching cycle. For example, when VBIAS is set to 5 volts, transistor 131 may pass drain voltage values that are equal to or less than5 volts minus the gate-to-source threshold of transistor 131, but otherwise clamp the voltage at the source of transistor 131 to a value of 5 volts minus the gate-to-source threshold when the drain voltage at drain terminal 111 is at a higher voltage level. Drain-sense comparator 132 may thus be implemented with low-voltage circuitry in any suitable manner that may compare the drain voltage DSENSE to a low-voltage drain threshold.

In some embodiments, the drain threshold may be negative relative to a source volage of source terminal 113. For example, the drain threshold may be set to -10 millivolts, -100 millivolts, or -1 volt relative to the source voltage at source terminal 113. Accordingly, drain-sense comparator 132 (and drain-sense circuit 130 as a whole) may detect a reverse current (also referred to in the art as a 3^{rd} quadrant current) through cascoded switch 110, from source terminal 113 to drain terminal 111. For example, when the drain voltage drops below the drain threshold during a reverse current condition, drain-sense comparator 132 may output a logic-high level for the drain comparison signal VDS_NEG to indicate that the reverse current is flowing through cascoded switch 110. In some embodiments, drain-sense comparator 132 may include hysteresis. For example, after triggering VDS_NEG based on an initial drain threshold of for example, -10 millivolts, -100 millivolts, or -1 volt relative to the source voltage at source terminal 113, the hysteresis built into drain-sense comparator 132 may require DSENSE to cross back above a hysteresis threshold that is either a positive voltage, a zero voltage, or a less negative voltage relative to the initial drain threshold. Accordingly, the hysteresis built into drain-sense comparator 132 may prevent oscillations of VDS_NEG when DSENSE is at or near the initial drain threshold for detecting the reverse current.

As shown in FIG. 2, logic gate 135 may be configured to receive the drain comparison signal VDS_NEG from drain-sense circuit 130 as well as the input signal IN. In some embodiments, the input signal IN may be a pulse-width modulated (PWM) input signal for turning on and off cascoded switch 110. Depending on the application, cascode-drive circuit 140 may be configured to receive a input signal whereby the logic-high level represents a turn-on command and a logic-low level represents a turn-off command, or vice versa whereby a logic-low level represents a turn-on command and a logic-high level represents a turn-off command. For the purposes of illustration, the embodiments below describe a logic-high level of the input signal IN as representing a turn-on command or an on-state of the input signal IN, and describe a logic-low level of the input signal IN as representing a turn-off command or an off-state of the input signal IN.

Logic gate 135 may be configured to output a cascode drive signal CASC based on the input signal IN and the drain comparison signal VDS_NEG. For the purposes of illustration, a logic-high level of the cascode drive signal CASC may represent a cascode-on signal while a logic-low level of the cascode drive signal CASC represents a cascode-off signal. Logic gate 135 may be implemented by any suitable logic circuit. In some embodiments, logic gate 135 may be implemented by an OR gate to implement an logic-OR function on IN and VDS_NEG. Accordingly, logic gate 135 may be configured to (i) assert a cascode-on signal in response to either of an on-state of the input signal IN or the drain voltage being less than the drain threshold as indicated by VDS_NEG, and (ii) assert a cascode-off signal in response to an off-state of the input signal IN and the drain voltage being greater than the drain threshold.

JFET drive circuit 141 may be configured to drive JFET 102 in a JFET on-state in response to the cascode-on signal (for example, a logic-high level of CASC). JFET drive circuit 141 may also be configured to drive JFET 102 in a JFET off-state in response to the cascode-off signal (for example, a logic-low level of CASC). In some embodiments, JFET drive circuit 141 may include JFET driver 142, switch 144, and/or capacitor 120. As described above, capacitor 120 may be considered part of cascode-drive circuit 140 (and JFET drive circuit 141) or as a component separate from cascode-drive circuit 140 (and JFET drive circuit 141).

JFET driver 142 may be configured to output a JFET-drive signal JDRIVE to capacitor 120 coupled in series between JFET driver 142 and the gate of JFET 102 in response to the output of logic gate 135, specifically the cascode drive signal CASC. When the cascode-on signal is asserted (for example, when CASC is at a logic-high level), JFET driver 142 may output a high JFET-drive signal JDRIVE at the level of the voltage supply VSUPPLY. In some embodiments, VSUPPLY may be for example, +8 volts, +12 volts, +15 volts, or more, relative to the voltage at source terminal 113, and depending on the gate thresholds of JFET 102 and/or MOSFET 104. For the purposes of illustration, embodiments are described below with a VSUPPLY of +15 volts relative to the voltage at source terminal 113.

As shown in FIG. 2, switch 144 may be coupled between the gate of JFET 102 and source terminal 113. In some embodiments, the switch 144 coupled between the gate of JFET 102 and the source terminal 113 may comprise a PMOS transistor. In other embodiments, switch 144 may comprise an NMOS transistor, or any other suitable switching device. Switch 144 may be configured to be responsive to the cascode-on signal (for example, a logic-high level of CASC) and the cascode-off signal (for example, a logic-low level of CASC). The cascode-on signal (a logic-high level of CASC) may drive switch 144 on, thereby coupling the gate of JFET 102 to source terminal 113. Accordingly, switch 144 may pull the JFET gate voltage JGATE down toward the voltage level of source terminal 113. As described above, JFET 102 may be a depletion-mode device that is normally on with a gate-to-source voltage of zero volts. Thus, switch 144 may drive JFET 102 in a JFET on-state in response to the cascode-on signal (for example, a logic-high level of CASC). And as described directly below, MOSFET drive circuit 160 may also drive MOSFET 104 in a MOSFET on-state in response to the cascode-on signal.

MOSFET drive circuit 160 may include logic circuit 170 and driver 180. Logic circuit 170 may be configured to receive the JFET-drive signal JDRIVE and the comparison signal JGATE_COMP. Logic circuit 170 may include buffer 171, inverter 172, AND-gate 173, and latch 174. In some embodiments, latch 174 may be a set-reset latch. Buffer 171 may receive the JFET-drive signal JDRIVE and output a signal to the set-input of the latch 174. Thus, when JFET-drive signal JDRIVE is driven high by JFET driver 142 in response to the assertion of the cascode-on signal (for example, a logic-high level of CASC), latch 174 may output a logic-high signal. Driver 180 may be coupled to drive the gate of MOSFET 104 in response to a logic-circuit output from latch 174. For example, in response to the logic-high signal from latch 174, driver 180 may output a high MOSFET-drive signal MDRIVE to drive MOSFET 104 in a MOSFET on-state. Thus, MOSFET drive circuit 160 may drive MOSFET 104 in a MOSFET on-state in response to the cascode-on signal (for example, a logic-high level of CASC). In some embodiments, driver 180 may be supplied by the same VSUPPLY as JFET driver 142. In other embodiments, such as shown in FIG. 2, driver 180 may be supplied by a low-voltage supply VSUPPLY_LV that may have a voltage of, for example, +5 volts relative to the voltage of source terminal 113, or any other voltage level suitable to drive MOSFET 104.

In sum, JFET 102 may be driven in a JFET on-state, and MOSFET 104 may be driven in a MOSFET on-state, in response to a cascode-on signal (for example, a logic-high level of the cascode drive signal CASC). Further, a voltage may be developed across the first terminal 121 and the second terminal 122 of capacitor 120. For example, in response to the logic-high level of CASC, switch 144 may hold the JFET-gate voltage JGATE at the second terminal 122 of capacitor 120 at the voltage level of source terminal 113. Meanwhile, JFET driver 142 may output a JFET-drive signal JDRIVE to the first terminal 121 of capacitor 120 at a level of, for example, +15 volts relative to the voltage at source terminal 113. As explained directly below, the voltage developed across capacitor 120 may be used to drive JFET 102 in an off-state in response to a subsequent cascode-off signal (for example, a logic-low level of the cascode drive signal CASC).

When the input signal IN transitions from a logic-high level (on-state) to a logic-low level (off-state), and no reverse current is detected by drain-sense circuit 130, logic gate 135 may assert a cascode-off signal (for example, a logic-low level of the cascode drive signal CASC). In response to the cascode-off signal, JFET driver 142 may output a low JFET-drive signal JDRIVE at the voltage level of source terminal 113. Further, in response to the cascode-off signal (a logic low level of the cascode drive signal CASC), switch 144 may turn off, thereby leaving the second terminal 122 of capacitor 120 and the gate of JFET 102 in a high-impedance state. Through the transition, capacitor 120 may maintain the relative +15 volts from first terminal 121 to second terminal 122. Thus, when JDRIVE at first terminal 121 transitions from +15 volts to zero volts relative to source terminal 113, capacitor 120 may force the JFET gate voltage JGATE at second terminal 122 to transition from zero volts to -15 volts relative to source terminal 113. As described above, JFET 102 may be a depletion-mode device with a gate-to-source threshold of, for example, -12 volts. Accordingly, the -15 volts applied by capacitor 120 to the gate of JFET 102 may drive JFET 102 in a JFET off-state. Cascode-drive circuit 140 together with capacitor 120 may thus directly drive JFET 102 in a JFET off-state in response to the cascode-off signal.

In some embodiments, the capacitance of capacitor 120 may be at least 10 nF, 20 nF, 40 nF, 100 nF, or more. Capacitor 120 may be sized, for example, to prevent the JFET gate voltage JGATE established by capacitor 120 from being significantly diminished due to the parasitic gate-to-drain capacitance or the parasitic gate-to-source capacitance. Thus, in some embodiments, the capacitance of capacitor 120 may be greater than a gate capacitance of JFET 102 by a factor of at least 10. For example, the capacitance of capacitor 120 may be greater than a gate capacitance of JFET 102 by a factor of 10, 20, 40, 100, or more.

Comparator 150 may be configured to compare the JFET gate voltage JGATE against a threshold VTH to generate a comparison signal JGATE_COMP. Comparator 150 may thus be utilized to provide an indication whether the JFET gate voltage JGATE is sufficient to drive JFET 102 in a JFET off-state when the cascode-off signal is asserted (for example, a logic-low level for CASC). As described in further detail below, MOSFET drive circuit 160 may drive MOSFET 104 in one of a MOSFET off-state and a MOSFET on-state in response to the comparison signal JGATE_COMP from comparator 150 and in response to the cascode-off signal. If the JFET gate voltage JGATE is sufficient to drive JFET 102 in a JFET off-state while the cascode-off signal is asserted (for example, when CASC is at a logic-low level), MOSFET drive circuit 160 may leave MOSFET 104 in a MOSFET on-state to save switching losses. Conversely, if the JFET gate voltage JGATE is not sufficient to drive JFET 102 in a JFET off-state when the cascode-off signal is asserted, MOSFET drive circuit 160 may drive MOSFET 104 in a MOSFET off-state to ensure that the conduction path of cascoded switch 110 as a whole is turned off.

As shown in FIG. 2, the reset-input to latch 174 may be coupled to the output of AND-gate 173. A first input of AND-gate 173 may be coupled to an output of inverter 172, which may invert the JFET-drive signal JDRIVE. Thus, when JDRIVE is low in response to a cascode-off signal, the first input to AND-gate 173 may be high. Under such conditions during assertion of the cascode-off signal (for example, a logic-low level of CASC), AND-gate 173 may pass the comparison signal JGATE_COMP at the second input of AND-gate 173 to the output of AND-gate 173.

Comparator 150 may compare the JFET gate voltage JGATE against a threshold VTH. In some embodiments, the threshold of comparator 150 may be set at or close to, for example, -12 volts to match a -12 volt gate-to-source threshold voltage of JFET 102. In embodiments where JFET 102 has a different gate-to-source threshold voltage, the threshold of comparator 150 may be correspondingly adjusted. The comparison signal JGATE_COMP may thus provide an indication as to whether the JFET gate voltage JGATE is sufficient to drive JFET 102 in a JFET off-state when the cascode-off signal is asserted by logic gate 135.

If the JFET gate voltage JGATE is -15 volts for example, and thus sufficiently below the example -12 volt threshold of JFET 102 to hold JFET 102 in a JFET off-state, comparator 150 may output a logic-low comparison signal JGATE_COMP. The output of AND-gate 173 may thus remain low, preventing the reset-input of latch 174 from being triggered. Driver 180 may thus maintain MOSFET 104 in a MOSFET on-state. Conversely, if the JFET gate voltage JGATE is at for example -11 volts and does not reach the -12 volt threshold, comparator 150 may output a logic-high comparison signal JGATE_COMP. The output of AND-gate 173 may thus go high, triggering the reset-input of latch 174. Latch 174 may accordingly output a low signal to driver 180, which may in turn drive MOSFET 104 in a MOSFET off-state.

In sum, MOSFET drive circuit 160 may be configured to drive MOSFET 104 in a MOSFET on-state in response to the cascode-on signal (for example, a logic-high level of the cascode drive signal CASC). Further, MOSFET drive circuit 160 may be configured to drive MOSFET 104 in one of a MOSFET off-state and the MOSFET on-state based on the comparison signal JGATE_COMP from the comparator 150 and in response to the cascode-off signal (for example, a logic-low level of the cascode drive signal CASC). Specifically, MOSFET drive circuit 160 may drive MOSFET 104 in the MOSFET on-state in response to an assertion of the cascode-off signal and comparator 150 indicating that the JFET gate voltage JGATE is sufficient to drive JFET 102 in a JFET off-state. Further, MOSFET drive circuit may drive MOSFET 104 in the MOSFET off-state in response to an assertion of the cascode-off signal and comparator 150 indicating that the JFET gate voltage JGATE is not sufficient to drive JFET 102 in a JFET off-state.

The operation of cascoded switch system 100 described herein may provide cascoded switch system 100 with multiple advantages. First, by directly driving the gate of JFET 102, the parasitic gate-to-drain capacitance of JFET 102 may help slow the switching transitions of cascoded switch 110, thereby reducing the transient voltage spikes that may be incurred at the drain of cascoded switch 110 due to, for example, the switching of inductive loads. Moreover, by directly driving the gate of JFET 102, the turn-on and turn-off time of JFET 102 and cascoded switch 110 as a whole may be further controlled. For example, in some embodiments, cascoded switch system 100 may further comprise a resistor coupled in series between capacitor 120 and the gate of JFET 102. In such embodiments, the resistor may help slow the turn-on and turn-off speed of JFET 102 and cascoded switch 110 as a whole, thereby further reducing the transient voltage spikes that may be incurred at the drain of cascoded switch 110 due to, for example, the switching of inductive loads. In addition, the operation of cascoded switch system 100 as described herein may reduce switching losses while still maintaining safe operation of cascoded switch 110. For example, if the JFET gate voltage JGATE is sufficient to drive JFET 102 in a JFET off-state during an assertion of the cascode-off signal, MOSFET drive circuit 160 may leave MOSFET 104 in a MOSFET on-state to save switching losses that would otherwise be associated with driving the gate of MOSFET 104 high and low to turn MOSFET 104 on and off. Conversely, if the JFET gate voltage JGATE is not sufficient to drive JFET 102 in a JFET off-state during an assertion of the cascode-off signal, MOSFET drive circuit 160 may drive MOSFET 104 in a MOSFET off-state to ensure that the conduction path of cascoded switch 110 as a whole is turned off and thereby maintains safe operation of cascoded switch 110.

In addition, cascoded switch system 100 may provide additional efficiencies by asserting the cascode-on signal in response to a reverse current detected through cascoded switch 110. For example, as described above with reference to FIG. 1, a power conversion system (such as power conversion system 10) may provide for a non-overlap time between the assertion of a high-side cascoded switch and a low-side cascoded switch. In applications (such as a buck switching power converter application shown in FIG. 1), a reverse current may flow through the low-side cascoded switch during the non-overlap time between the time that high-side cascoded switch turns off and the subsequent time that low-side cascoded switch turns on. Such a reverse current during this non-overlap time may cause a power loss across JFET 102 and also across the body diode of MOSFET 104. By detecting the reverse current with drain-sense circuit 130, and driving cascoded switch 110 in an on-state in response thereto, the power loss that may otherwise be induced by the reverse current may be minimized, therefore improving the energy efficiency of cascoded switch system 100.

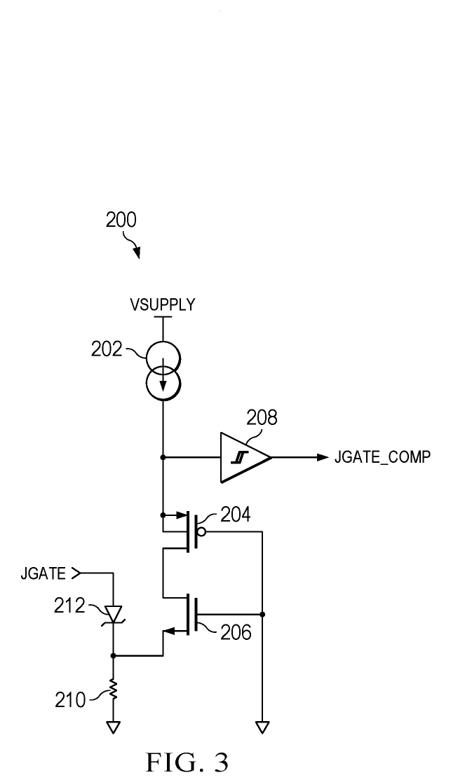

FIG. 3 illustrates a schematic diagram of comparator 200 in accordance with embodiments of the present disclosure. Comparator 200 may represent an embodiment of comparator 150 described above with reference to FIG. 2. As shown in FIG. 3, comparator 200 may include current source 202, transistor 204, transistor 206, buffer 208, resistor 210 and Zener diode 212.

Comparator 200 may be configured to compare the JFET gate voltage JGATE to a threshold. In the embodiment illustrated in FIG. 3, the reverse breakdown voltage of Zener diode 212 may provide the threshold against which the JFET gate voltage JGATE is compared.

Transistor 204 may be a P-type MOSFET (PMOS) and transistor 206 may be an N-type MOSFET (NMOS). The source of transistor 204 may be coupled to receive a current from current source 202, and the drain of transistor 204 may be coupled to the drain of transistor 206. The source of transistor 206 may in turn be coupled to the intermediate node between Zener diode 212 and resistor 210. The gates of transistor 204 and transistor 206 may be tied low, for example to the source terminal 113 of cascoded switch system 100, which as described above with reference to FIG. 2, may serve as the low voltage rail for cascoded switch system 100.

When JGATE drops to a negative voltage below the negative breakdown of Zener diode 212, Zener diode 212 may pull the voltage at the source of transistor 206 low to a negative voltage, thereby turning on transistor 206. When transistor 206 turns on, transistor 204 and transistor 206 may sink the current from current source 202, lowering the voltage at the input of buffer 208. Buffer 208 may in turn output a logic-low comparison signal JGATE_COMP indicating that the JFET gate voltage JGATE is sufficient to drive JFET 102 in a JFET off-state.

If JGATE does not reach a negative voltage below the negative breakdown of Zener diode 212, Zener diode 212 will not conduct, and the voltage at the source of transistor 206 may match the voltage at the gate of transistor 206. Accordingly, transistor 206 may block the current from current source 202, causing the voltage at the input of buffer 208 to go high. Buffer 208 may in turn output a logic-high comparison signal JGATE_COMP indicating that the JFET gate voltage JGATE is not sufficient to drive JFET 102 in a JFET off-state.

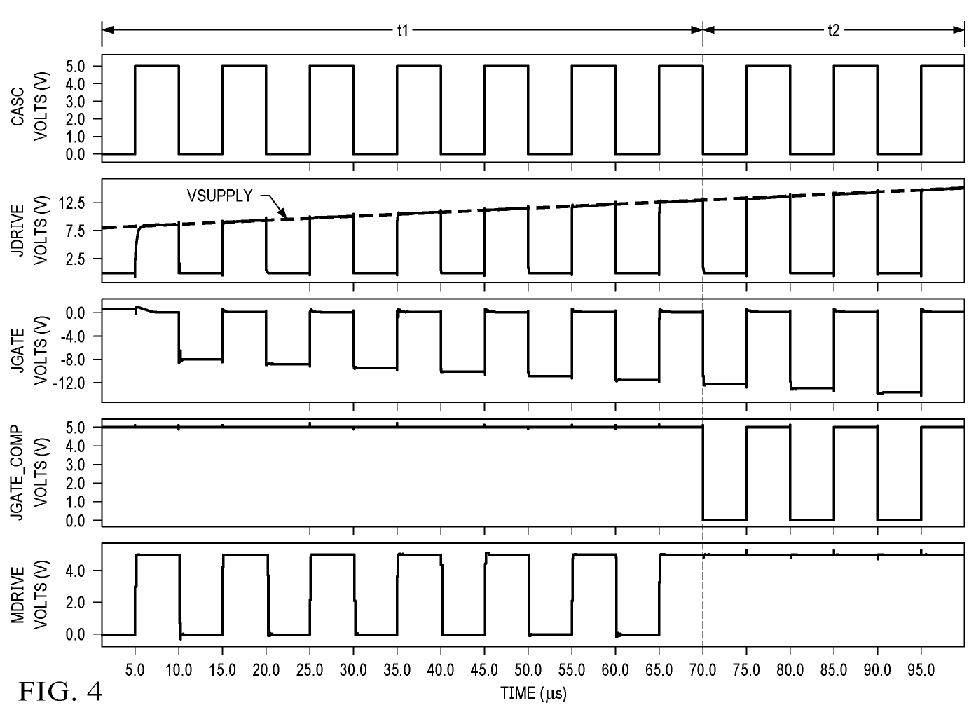

FIG. 4 illustrates a plot diagram of example waveforms within cascoded switch system 100 in accordance with embodiments of the present disclosure. Specifically, FIG. 4 illustrates how the JFET drive signal JDRIVE, the JFET gate voltage JGATE, the comparison signal JGATE_COMP, and the MOSFET drive signal MDRIVE respond to repeated cycles of the cascode drive signal CASC as the supply voltage VSUPPLY increases over time. For simplicity, the waveforms in FIG. 4 illustrate the aforementioned signals in an example application where the cascoded switch system 100 is implemented as a low-side switch with the source terminal 113 of cascoded switch system 100 held to zero volts at ground.

As shown in FIG. 4, the cascode drive signal CASC may cycle between a logic-high level (representing a cascode-on signal) and a logic-low level (representing a cascode-off signal). When CASC is at logic-high level (representing a cascode-on signal), the JFET drive signal JDRIVE may be at a high voltage equal to the level of the voltage supply VSUPPLY, and the JFET gate voltage JGATE may be forced to zero volts. When CASC transitions to a logic-low level (representing a cascode-off signal), the JFET drive signal JDRIVE may be forced low to zero volts. As described above with reference to FIG. 2, capacitor 120 may maintain the voltage across first terminal 121 and second terminal 122 when the JFET drive signal JDRIVE transitions high to low. Thus, when CASC transitions to a logic-low level, and the JFET drive signal JDRIVE transitions from a high voltage level equal to VSUPPLY to zero volts, capacitor 120 may force the JFET gate voltage JGATE to transition from zero volts to a negative voltage having the same magnitude as VSUPPLY.

As described above with reference to FIG. 2, comparator 150 may compare the JFET gate voltage JGATE against a threshold corresponding to the gate-to-source threshold of JFET 102. For example, the threshold of comparator 150 may be set to -12 volts to correspond to a -12 volt gate-to-source threshold of JFET 102. Accordingly, the comparison signal JFET_COMP from comparator 150 may indicate whether the negative voltage applied to the gate of JFET 102 has a sufficient magnitude to drive JFET 102 in a JFET off-state during an assertion of the cascode-off signal.

During time period t1 shown in FIG. 4, VSUPPLY may be less than +12 volts. Thus, the negative voltages applied by capacitor 120 to the gate of JFET 102 during the assertions of the cascode-off signal within time period t1 may not have a sufficiently negative magnitude to drive JFET 102 in a JFET off-state. Comparator 150 may thus output a logic-high level comparison signal JGATE_COMP to indicate that the JFET gate voltage is not sufficient to drive JFET in an off-state throughout time period t1. In response to the comparison signal JGATE_COMP, MOSFET drive circuit 160 may output a low MOSFET drive signal MDRIVE during each assertion of the cascode-off signal (for example, each logic-low state of CASC) throughout time period t1. MOSFET drive circuit 160 may thus drive MOSFET 104 in a MOSFET off-state during each assertion of the cascode-off signal throughout time period t1. MOSFET drive circuit 160 may thus ensure that the conduction path of cascoded switched 110 is turned off during the assertion of the cascode-off signal, even when the supply voltage is insufficient to generate a sufficiently negative voltage to drive JFET 102 in an off-state.

Moving to time period t2, the supply voltage VSUPPLY crosses +12 volts. Thus, the magnitude of the negative voltage applied by capacitor 120 to the gate of JFET 102 during the assertion of the cascode-off signal may cross the -12 volt threshold required to drive JFET 102 in an off-state. Thus, during time period t2, JFET 102 may be cyclically driven on and off following cascode drive signal CASC. Further, during time period t2, comparator 150 may output a logic-low comparison signal JGATE_COMP to indicate that the JFET gate voltage JGATE during the off-state of the input signal IN is sufficient to drive JFET 102 in a JFET off-state. In response to the comparison signal JGATE_COMP, MOSFET drive circuit 160 may maintain the MOSFET drive signal MDRIVE at a high level throughout time period t2. MOSFET 104 may thus be driven in a MOSFET on-state throughout time period t2. Because JFET 102 is cycling on and off in response to the cascode drive signal CASC throughout time period t2, it may not be necessary to also cycle MOSFET on and off. And by maintaining MOSFET 104 in an on-state throughout time period t2, switching losses associated with turning on and off MOSFET 104 may be avoided thereby improving the efficiency of the system in which cascoded switch system 100 is implemented.

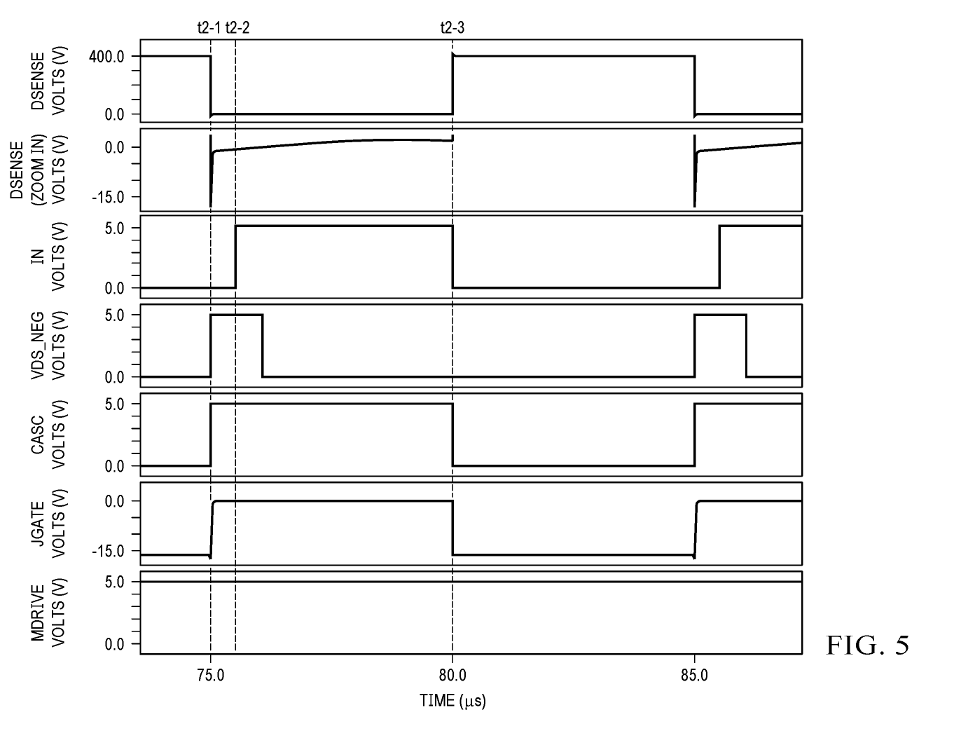

FIG. 5 illustrates a plot diagram of example waveforms within cascoded switch system 100 in accordance with embodiments of the present disclosure. Specifically, FIG. 5 illustrates how the cascode-drive signal CASC is controlled based on the input signal IN and the drain comparison signal VDS_NEG during the time period t2 shown in FIG. 4. For simplicity, the waveforms in FIG. 5 illustrate the aforementioned signals in an example application where the cascoded switch system 100 is implemented on the low-side of an H-bridge application, such as a buck switching power converter shown in FIG. 1. Accordingly, as described above with reference to FIG. 1, a reverse current may flow through the low-side cascoded switch (for example, cascoded switch 110) during the non-overlap time between the time that high-side cascoded switch turns off and the subsequent time that low-side cascoded switch turns on.

At time t2-1 in FIG. 5, the reverse current through cascoded switch 110 may begin to flow from source terminal 113 (which may be coupled to ground GND) to drain terminal 111. Accordingly, the sensed drain voltage DSENSE at drain terminal 111 may drop to a negative voltage relative to the source terminal 113 (which is coupled here to ground). When DSENSE crosses below the drain threshold, drain-sense circuit 130 (and drain-sense comparator 132 in particular) may assert the drain comparison signal VDS_NEG at a logic-high level, therefore causing logic gate 135 to output the cascode-drive signal CASC signal at a logic-high level (which represents a cascode-on signal). Accordingly, JGATE is forced high to drive JFET 102 in a JFET on-state. This JFET on-state may force cascoded switch 110 as a whole to operate in an on-state as MDRIVE is already high to drive MOSFET 104 in a MOSFET on-state. By turning on JFET 102 (and cascoded switch 110 as a whole) in response to detecting the reverse current, the voltage drop across cascoded switch 110 due to the reverse current may be reduced. Accordingly, the power that would otherwise be dissipated by cascoded switch 110 due to the reverse current may be reduced. The non-overlap time between turning off the high-side cascoded switch and turning on the low-side cascoded switch may be reduced while still maintaining a safety guarantee that the low-side cascoded switch does not turn on until the reverse current is detected (which indicates that the high-side has been sufficiently turned off to prevent shoot-through).

At time t2-2, the input signal IN may be asserted at a logic-high level and may continue at a logic-high level until time t2-3. Between time t2-2 and time t2-3, the magnitude of the reverse current through cascoded switch 110 may be reduced and the current through cascoded switch 110 may revert to a positive current. Accordingly, the drain sense voltage DSENSE may cross back above the drain threshold between time t2-2 and time t2-3 and VDS_NEG may be de-asserted. Because the input signal IN remains at a logic-high level during this time, the cascode-drive signal CASC may remain at a logic-high level (representing a cascode-on signal) despite the de-assertion of VDS_NEG.

At time t2-3, the input signal IN may be de-asserted to a logic-low level. With VDS_NEG also de-asserted, the logic gate 135 may force the cascode drive signal CASC to a logic-low level (representing a cascode-off signal). According, JFET drive circuit 141 may drive the JFET gate voltage JGATE low (for example -15 volts) to force JFET 102 in a JFET off-state. By driving JFET 102 in a JFET off-state, cascoded switch 110 as whole may be forced into an off-state. As shown in FIG. 5, MDRIVE may be kept high during this time to save the switching loss that would otherwise be incurred by also switching MOSFET 104 off and on as the JFET 102 is switched off and on.

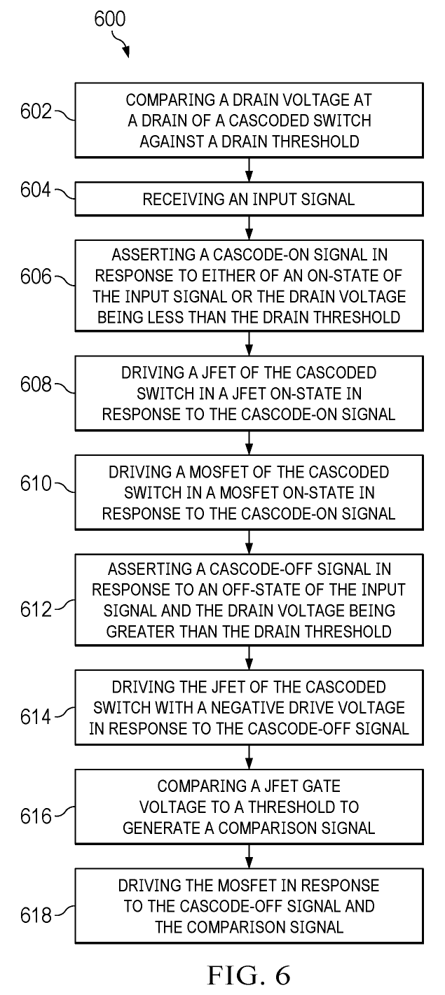

FIG. 6 illustrates an example method 600 of operating a cascoded switch system in accordance with embodiments of the present disclosure. Method 600 may be performed by any suitable mechanism, such as capacitor 120, cascode-drive circuit 140, JFET drive circuit 141, JFET driver 142, switch 144, comparator 150, MOSFET drive circuit 160, and/or any suitable combination thereof. Method 600 may be performed with fewer or more steps than shown in FIG. 6. Moreover, steps of method 600 may be omitted, repeated, performed in parallel, performed in a different order than shown in FIG. 6, or performed recursively. One or more steps of method 600, although shown in an order, may be performed at the same time or in a re-ordered manner.

Step 602 may include comparing a drain voltage at a drain of a cascoded switch against a drain threshold. For example, as described above with reference to FIG. 2, drain-sense circuit 130 may compare a drain voltage DSENSE at the drain terminal 111 against a drain threshold to produce a drain comparison signal VDS_NEG.

Step 604 may include receiving a input signal. For example, as described above with reference to FIG. 2, logic gate 135 may receive the drain comparison signal VDS_NEG from drain-sense circuit 130 as well as the input signal IN via input terminal 101.

Step 606 may include asserting a cascode-on signal in response to either of an on-state of the input signal or the drain voltage being less than the drain threshold. For example, as described above with reference to FIG. 2, logic gate 135 may be configured to output a cascode drive signal CASC based on the input signal IN and the drain comparison signal VDS_NEG. In some embodiments, logic gate 135 may be implemented by an OR gate to implement an logic-OR function on IN and VDS_NEG. Accordingly, logic gate 135 may be configured to assert a cascode-on signal in response to either of an on-state of the input signal IN or the drain voltage being less than the drain threshold as indicated by VDS_NEG.

Step 608 may include driving a JFET of the cascoded switch in a JFET on-state in response to the cascode-on signal. For example, as described above with reference to FIG. 2, JFET drive circuit 141 may drive JFET 102 in a JFET on-state in response to the cascode-on signal (for example, a logic-high level of CASC). In some embodiments, step 608 may further include charging a capacitor coupled in series with a gate of the JFET when driving the JFET in the JFET on-state. For example, as described above with reference to FIG. 2, in response to the cascode-on signal (a logic-high level of CASC), switch 144 may hold the JFET-gate voltage JGATE at the voltage level of source terminal 113 to drive JFET 102 in a JFET on-state. The second terminal 122 of capacitor 120 may be coupled to the gate of JFET 102, and may thus also be held at the voltage level of source terminal 113. Meanwhile, JFET driver 142 may output a JFET-drive signal JDRIVE to the first terminal 121 of capacitor 120 at a level of, for example, +15 volts relative to the voltage at source terminal 113. Thus, JFET driver 142 may charge capacitor 120, which is coupled in series with the gate of JFET 102, when JFET 102 is in the JFET on-state.

Step 610 may include driving a MOSFET of the cascoded switch in a MOSFET on-state in response to the cascode-on signal. For example, as described above with reference to FIG. 2, MOSFET drive circuit 160 may drive MOSFET 104 in a MOSFET on-state in response to the cascode-on signal (for example, a logic-high level of CASC). Specifically, the cascode-on signal may cause JFET driver 142 to output a high JFET-drive signal JDRIVE. Buffer 171 may receive the JFET-drive signal JDRIVE and in turn output a signal to the set-input of the latch 174. Thus, when JFET-drive signal JDRIVE is driven high by JFET driver 142 in response to the assertion of the cascode-on signal (for example, a logic-high level of CASC), latch 174 may output a logic-high signal. Driver 180 may be coupled to drive the gate of MOSFET 104 in response to a logic-circuit output from latch 174. For example, in response to the logic-high signal from latch 174, driver 180 may output a high MOSFET-drive signal MDRIVE to drive MOSFET 104 in a MOSFET on-state.

Step 612 may include asserting a cascode-off signal in response to an off-state of the input signal and the drain voltage being greater than the drain threshold. For example, as described above with reference to FIG. 2, logic gate 135 may be implemented by an OR gate to implement an logic-OR function on IN and VDS_NEG. Accordingly, logic gate 135 may be configured to assert a cascode-off signal (represented by a logic-low level of CASC) in response to a logic-low off-state level of the input signal IN and a logic-low level of VDS_NEG indicating that the drain voltage DSENSE is greater than the drain threshold.

Step 614 may include driving the JFET of the cascoded switch with a negative drive voltage in response to the cascode-off signal. For example, as described above with reference to FIG. 2, when the input signal IN transitions from a logic-high level (on-state) to a logic-low level (off-state), and no reverse current is detected by drain-sense circuit 130, logic gate 135 may assert a cascode-off signal (for example, a logic-low level of the cascode drive signal CASC). In response to the cascode-off signal, JFET driver 142 may output a low JFET-drive signal JDRIVE at the voltage level of source terminal 113. Further, in response to the cascode-off signal, switch 144 may turn off, thereby leaving the second terminal 122 of capacitor 120 and the gate of JFET 102 in a high-impedance state. Through the transition, capacitor 120 may maintain the relative +15 volts from first terminal 121 to second terminal 122. Thus, when JDRIVE at first terminal 121 transitions from +15 volts to zero volts relative to source terminal 113, capacitor 120 may force the JFET gate voltage JGATE at second terminal 122 to transition from zero volts to a negative drive voltage (for example, -15 volts) relative to source terminal 113. Accordingly, the voltage stored across capacitor 120 may be applied as the negative drive voltage in response to the cascode-off signal.

Step 616 may include comparing a JFET gate voltage to a threshold to generate a comparison signal. For example, as described above with reference to FIG. 2, comparator 150 may be configured to compare the JFET gate voltage JGATE against a threshold VTH to generate a comparison signal JGATE_COMP. Comparator 150 may thus be utilized to provide an indication whether the negative drive voltage applied to JGATE is sufficient to drive JFET 102 in a JFET off-state when the cascode-off signal is asserted.

Step 618 may include driving the MOSFET in response to the cascode-off signal and the comparison signal. As described above with reference to FIG. 2, driving MOSFET 104 in response to the cascode-off signal and the comparison signal may include (i) driving MOSFET 104 in the MOSFET on-state in response to an assertion of the cascode-off signal and the comparison signal indicating that the JFET gate voltage JGATE is sufficient to drive JFET 102 in a JFET off-state, and (ii) driving MOSFET 104 in a MOSFET off-state in response to an assertion of the cascode-off signal and the comparison signal indicating that the JFET gate voltage JGATE is not sufficient to drive the JFET in a JFET off-state.

Although examples have been described above, other modifications and variations may be made from this disclosure without departing from the spirit and scope of these examples. The above descriptions of various embodiments illustrate the principles of the invention. Numerous variations and modifications will become apparent to those skilled in the art based on the above disclosure. The following claims are intended to embrace all such variations and modifications.

1. A cascoded switch system, comprising:
a cascoded switch comprising a JFET and a MOSFET coupled in series between a drain terminal and a source terminal of the cascoded switch; and
a cascode-drive circuit comprising:
a drain-sense circuit configured to compare a drain voltage at the drain terminal against a drain threshold;
a logic gate configured to:
assert a cascode-on signal in response to either of an on-state of an input signal or the drain voltage being less than the drain threshold; and
assert a cascode-off signal in response to an off-state of the input signal and the drain voltage being greater than the drain threshold;
a JFET drive circuit configured to:
drive the JFET in a JFET on-state in response to the cascode-on signal; and
drive the JFET with a negative voltage in response to the cascode-off signal;
a comparator configured to compare a JFET gate voltage against a JFET-gate threshold; and
a MOSFET drive circuit configured to:
drive the MOSFET in a MOSFET on-state in response to the cascode-on signal; and
drive the MOSFET in one of a MOSFET off-state and the MOSFET on-state based on a comparison signal from the comparator and in response to the cascode-off signal.

2. The cascoded switch system of claim 1, wherein the drain threshold is negative relative to a source voltage of the source terminal.

3. The cascoded switch system of claim 1, wherein the MOSFET drive circuit is configured to drive the MOSFET in the MOSFET on-state in response to an assertion of the cascode-off signal and the comparator indicating that the JFET gate voltage is sufficient to drive the JFET in a JFET off-state.

4. The cascoded switch system of claim 1, wherein the MOSFET drive circuit is configured to drive the MOSFET in the MOSFET off-state in response to an assertion of the cascode-off signal and the comparator indicating that the JFET gate voltage is not sufficient to drive the JFET in a JFET off-state.

5. The cascoded switch system of claim 1, wherein:
the JFET is a silicon carbide JFET; and
the MOSFET is a silicon MOSFET.

6. The cascoded switch system of claim 1, wherein the JFET, the MOSFET, and the cascode-drive circuit are co-packaged in a multi-die integrated circuit package.

7. The cascoded switch system of claim 1, wherein the JFET drive circuit comprises:
a JFET driver coupled to output a JFET-drive signal to a capacitor coupled in series between the JFET driver and a gate of the JFET in response to an output of the logic gate; and
a switch coupled between the gate of the JFET and the source terminal, the switch configured to be responsive to the output of the logic gate.

8. The cascoded switch system of claim 7, wherein a capacitance of the capacitor is greater than a gate capacitance of the JFET by a factor of at least 10.

9. The cascoded switch system of claim 7, wherein a capacitance of the capacitor is at least 10 nF.

10. The cascoded switch system of claim 7, further comprising a resistor coupled in series between the capacitor and the gate of the JFET.

11. The cascoded switch system of claim 7, wherein the switch coupled between the gate of the JFET and the source terminal comprises a PMOS transistor.

12. A cascoded switch system, comprising:
a cascoded switch comprising a JFET and a MOSFET coupled in series between a drain terminal and a source terminal of the cascoded switch; and
a cascode-drive circuit comprising:
a drain-sense circuit configured to compare a drain voltage at the drain terminal against a drain threshold;
a logic gate configured to:
assert a cascode-on signal in response to either of an on-state of an input signal or the drain voltage being less than the drain threshold; and
assert a cascode-off signal in response to an off-state of the input signal and the drain voltage being greater than the drain threshold;
a JFET drive circuit configured to:
drive the JFET in a JFET on-state in response to the cascode-on signal; and
drive the JFET with a negative voltage in response to the cascode-off signal;
a comparator configured to compare a JFET gate voltage against a JFET-gate threshold; and
a MOSFET drive circuit configured to:
drive the MOSFET in a MOSFET on-state in response to the cascode-on signal; and
drive the MOSFET in the MOSFET on-state in response to an assertion of the cascode-off signal and the comparator indicating that the JFET gate voltage is sufficient to drive the JFET in a JFET off-state; and
drive the MOSFET in an MOSFET off-state in response to the assertion of cascode-off signal and the comparator indicating that the JFET gate voltage is not sufficient to drive the JFET in the JFET off-state.

13. The cascoded switch system of claim 12, wherein the drain threshold is negative relative to a source voltage of the source terminal.

14. The cascoded switch system of claim 12, wherein the JFET, the MOSFET, and the cascode-drive circuit are co-packaged in a multi-die integrated circuit package.

15. A method, comprising:
comparing a drain voltage at a drain of a cascoded switch against a drain threshold;
receiving a input signal;
asserting a cascode-on signal in response to either of an on-state of the input signal or the drain voltage being less than the drain threshold;
driving a JFET of the cascoded switch in a JFET on-state in response to the cascode-on signal;
driving a MOSFET of the cascoded switch in a MOSFET on-state in response to the cascode-on signal;
asserting a cascode-off signal in response to an off-state of the input signal and the drain voltage being greater than the drain threshold;
driving the JFET of the cascoded switch with a negative drive voltage in response to the cascode-off signal;
comparing a JFET gate voltage to a threshold to generate a comparison signal; and
driving the MOSFET in response to the cascode-off signal and the comparison signal.

16. The method of claim 15, wherein driving the MOSFET in response to the cascode-off signal and the comparison signal comprises driving the MOSFET in the MOSFET on-state in response to an assertion of the cascode-off signal and the comparison signal indicating that the JFET gate voltage is sufficient to drive the JFET in a JFET off-state.

17. The method of claim 15, wherein driving the MOSFET in response to the cascode-off signal and the comparison signal comprises driving the MOSFET in a MOSFET off-state in response to an assertion of the cascode-off signal and the comparison signal indicating that the JFET gate voltage is not sufficient to drive the JFET in a JFET off-state.

18. The method of claim 15, wherein the drain threshold is negative relative to a source voltage of a source terminal of the cascoded switch.

19. The method of claim 15, further comprising:
charging a capacitor coupled in series with a gate of the JFET when driving the JFET in the JFET on-state; and
applying a voltage stored across the capacitor as the negative drive voltage in response to the cascode-off signal.

20. The method of claim 15, wherein:
the JFET is a silicon carbide JFET; and
the MOSFET is a silicon MOSFET.
